(19) United States
(12) Patent Application Publication
(10) Pub. No.: US 2007/0228412 A1
(43) Pub. Date: Oct. 4, 2007

(54) Low voltage triggering silicon controlled rectifier and circuit thereof

(75) Inventors: Sheng Yuan Yang, Sanchong City (TW); Cheng Yu Fang, Hsinchu City (TW)

Correspondence Address: John S. Egbert;Egbert Law Offices, 7th Floor, 412 Main Street, Houston, TX, 77002, US

(73) Assignee: ADVANCED ANALOG TECHNOLOGY, INC., Hsinchu (TW)

(21) Appl. No.: 11/443,963

(22) Filed: May 30, 2006

(30) Foreign Application Priority Data
Mar. 29, 2006 (TW) 095110868

(51) Int. Cl. H01L 29/74

(52) U.S. Cl. 257/173; 257/E23.071

(57) ABSTRACT

A low voltage triggering silicon controlled rectifier (LVTSCR) is disclosed. The LVTSCR utilizes an added resistor disposed in a second doped region between the anode of the LVTSCR and the emitter of the parasitical bipolar PNP transistor to increase the holding voltage thereof when the LVTSCR is triggered. The LVTSCR includes a semiconductor substrate with a first conductive type and a gate. The semiconductor substrate includes a first doped region with a second conductive type, a second doped region with the first conductive type, a third doped region with the second conductive type, a fourth doped region with the second conductive type and a fifth doped region with the first conductive type. The gate is applied with a lower triggering voltage to trigger the LVTSCR.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates to a low voltage triggering silicon controlled rectifier (LVTSCR) and a circuit thereof, and more particularly, to a low voltage triggering silicon controlled rectifier and a circuit thereof with high holding voltage and low triggering voltage.

### BACKGROUND OF THE INVENTION

The issue of electrostatic discharge (ESD) is common in the manufacturing and use of integrated circuits (ICs). With rapid growth in demand for high-speed computation and broadband wireless communication products, and the reduction in size of current integrated circuits from 80 nanometers down to 65 nanometers, the elements in an IC become tiny and sensitive to instant electrostatic discharge. Therefore, the quality of ICs is seriously influenced by the ESD; and the ESD issue becomes more important with improvement of the manufacturing process of ICs.

Currently, the international ESD specification for commercial ICs (i.e., component-level ESD specification) defines three ESD endurances for HBM (human body model), MM (machine model), and CDM (charged device model), as above 2000 volts, above 200 volts, and 1000 volts, respectively. In general, the ESD occurs in a very short duration of time, ranging from 10 nanoseconds to 100 nanoseconds, and an on-chip ESD protection apparatus or circuit is required to avoid damage to ICs.

A qualified ESD protection apparatus must meet the following requirements: (1) in normal operation, the ESD protection apparatus is in an off state; and (2) when the ESD event occurs, the ESD protection apparatus must actuate immediately. As far as the performance per area is concerned, the SCR (silicon controlled rectifier) presents the most effective choice of various ESD protection apparatuses. The SCR can provides an effective ESD protection mechanism, in which when the ESD event occurs, the SCR decreases its impedance immediately, actuating from “off” state to “on” state, to accept most of the current caused by the ESD. Thus, a reliable and on-chip ESD protection is provided for an IC chip. In addition, the heat generated by the SCR in conductive state is distributed uniformly thereon and therefore, the damage to the IC chip due to local heat spots is avoided.

With the improvement of IC manufacturing technology, a transistor with a decreasing breakdown voltage is easily subject to a weak ESD. Therefore, a LVTSCR with a triggering voltage below 30 volts is developed to prevent the IC chip from damage by the ESD.

FIG. 1(a) shows a circuit of a conventional LVTSCR applied in the ESD protection apparatus. An NMOS transistor M is coupled to the collector and the emitter of a parasitical bipolar transistor Q2, and the parasitical bipolar NPN transistor Q2 is coupled to a resistance R2. Since the breakdown voltage of the NMOS transistor M is designed to be less than that of the parasitical bipolar NPN transistor Q2 with the same gate length, the NMOS transistor M will turn on before the parasitical bipolar NPN transistor Q2 turns on to reduce the triggering voltage of the LVTSCR. When the NMOS transistor M is in conductive state, the current acting thereon will turn on the parasitical bipolar NPN transistor Q2. In the meantime, the current acting on the parasitical bipolar NPN transistor Q2 will turn on a parasitical bipolar PNP transistor Q1 which is coupled to a resistance R1. The current acting on the parasitical bipolar PNP transistor Q1 enhances the current conduction on the parasitical bipolar NPN transistor Q2. As a result, a current positive feedback formed by the parasitical bipolar PNP transistor Q1 and the parasitical bipolar NPN transistor Q2, which is similar to one characteristic of a PNPN SCR, is called latch-up. When the LVTSCR is in the latch-up state, the electrostatic charges at a bonding pad (not shown) connected to the anode flow to the ground though the cathode. Accordingly, the LVTSCR can be applied in the ESS protection apparatus; that is, the charges at the bonding pad can be quickly removed to the ground.

FIG. 1(b) illustrates a structural cross-section regarding FIG. 1(a). Referring to FIG. 1(b), an N-well 11, a heavily doped N region 15, and a heavily doped P region 16 are formed in a P-substrate 10. A heavily doped N region 12 and a heavily doped P region 13 are formed in the N-well 11. A heavily doped N region 14 is disposed at the interface of the P-substrate 10 and the N-well 11. A gate 17 disposed between the heavily doped N region 14 and the heavily doped N region 15 is used to control the conduction thereof. The gate 17, the heavily doped N region 14 and the heavily doped N region 15 form the NMOS transistor M of FIG. 1(a). The heavily doped N region 15, the heavily doped P region 16, and the gate 17 are grounded through the cathode. The heavily doped N region 12 and the heavily doped P region 13 are connected to the bonding pad (not shown) through the anode. The heavily doped P region 13, the N-well 11, and the P-substrate 10 form the parasitical bipolar PNP transistor Q1 of FIG. 1(a). The heavily doped N region 15, the P-substrate 10, and the N-well 11 form the parasitical bipolar NPN transistor Q2 of FIG. 1(a). Since the N-well 11 is used by the two bipolar transistors Q2 and Q1, the base of Q1 connecting to the collector of Q2, the PNPN SCR structure is formed.

The holding voltage of a general conventional ESD protection apparatus containing an SCR (e.g., FIGS. 1(a) and 1(b)) is below 5 volts. The SCR or a circuit protected by the SCR, which is fabricated by CMOS manufacturing processes, may utilize a source voltage larger than the holding voltage of the SCR and results in a latch-up off problem. That is, the inability to shut off the latch-up condition after the ESD event or after a power surge or spike in the circuit. Thus, the ESD protection apparatus with a low holding voltage SCR cannot be applied for power supply protection.

Therefore, to effectively avoid the latch-up shut off problem and erroneous state reset, an SCR with low triggering voltage and high holding voltage (higher than the source voltage) needs to be developed.

### BRIEF SUMMARY OF THE INVENTION

The objective of the present invention is to provide a low voltage triggering silicon controlled rectifier (LVTSCR), which utilizes a resistor between the anode of the LVTSCR and the emitter of the parasitical PNP bipolar transistor thereof to increase the holding voltage thereof and leave the triggering voltage thereof unchanged. The LVTSCR is fabricated with a 0.6 pm CMOS technology and exhibits a triggering voltage below 15 volts.

Another objective of the present invention is to provide a low voltage triggering silicon controlled rectifier circuit with a resistor added between a first node of the circuit and the emitter of a first transistor. Thus, the holding voltage of the circuit is increased but the triggering voltage thereof is maintained. The triggering voltage of the circuit of the present invention is below 15 volts.

In order to achieve the objectives, the present invention discloses a low voltage triggering silicon controlled rectifier circuit comprising a first resistor, a second resistor, a third resistor, a first transistor, a second transistor and a third transistor. The emitter of the first transistor is connected to a first node through the third resistor; the collector thereof is connected to a second node through the second resistor; and the base thereof is connected to the first node through the first transistor. The base of the second transistor is connected to the collector of the first transistor; the emitter thereof is connected to the second node; the collector thereof is connected to the base of the first transistor. The gate and the source of the third transistor are connected to the second node; the drain thereof is connected to the collector of the second transistor, wherein the breakdown voltage of the third transistor is lower than that of the second transistor.

The present invention also discloses a low voltage triggering silicon controlled rectifier comprising a semiconductor substrate with a first conductive type and a gate. The semiconductor substrate comprises a first doped region with a second conductive type, a second doped region with the first conductive type, a third doped region with the second conductive type, fourth doped region with the second conductive type and a fifth doped region with the first conductive type. The second doped region is disposed in the first doped region to be an added resistor whose resistance determines the holding voltage of the low voltage triggering silicon controlled rectifier. The third doped region is disposed at the interface of the first doped region and the semiconductor substrate. The doping concentrations of the third and fourth doped regions are higher than that of the first doped region, and the doping concentrations of the second and the fifth doped regions are higher than that of the semiconductor substrate. The gate is disposed on the semiconductor substrate to control the conduction between the third and the fourth doped regions. The second and the third doped regions are connected in parallel to the anode. The gate and the fourth and fifth doped regions are connected in parallel to the cathode.

With the added resistor in the second doped region, the LVTSCR of the present invention is capable of increasing the holding voltage thereof and maintaining the triggering voltage thereof such that it presents a low triggering voltage (i.e., below 15 volts) and a high holding voltage (i.e., above 3.5 volts).

### BRIEF DESCRIPTION OF THE SEVERAL VIEWS OF THE DRAWINGS

The invention will be described according to the appended drawings.

FIG. 1(a) shows a schematic view of a circuit of a conventional LVTSCR applied in the ESD protection apparatus.

FIG. 1(b) illustrates a structural cross-section view regarding the circuit of FIG. 1(a).

FIG. 2 is a schematic view showing the equivalent circuit of the low voltage triggering silicon controlled rectifier of the present invention.

FIG. 3(a) illustrates a structural cross-section view of one embodiment of the LVTSCR of the present invention.

FIG. 3(b) is the top view of FIG. 3(a).

FIG. 4 shows a graph illustration of the I-V curves of the LVTSCRs regarding FIG. 3(a) with different equivalent widths.

FIG. 5 illustrates a structural cross-section view of another embodiment of the LVTSCR of the present invention.

### DETAILED DESCRIPTION OF THE INVENTION

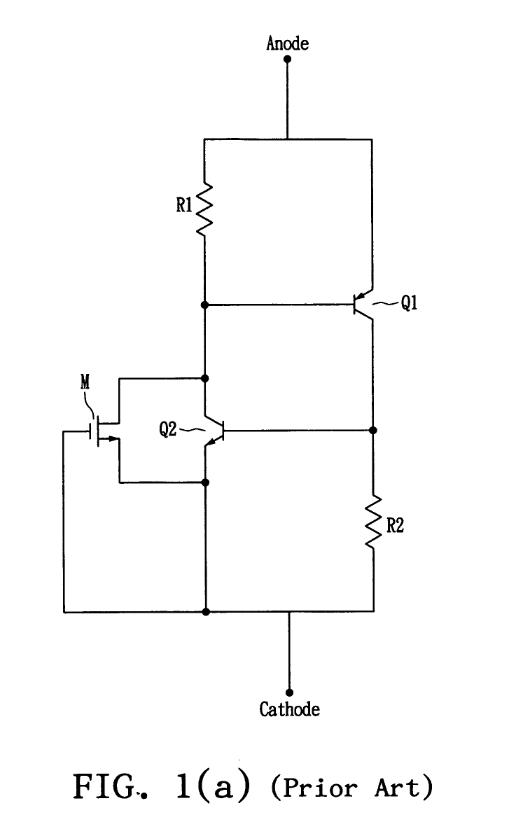

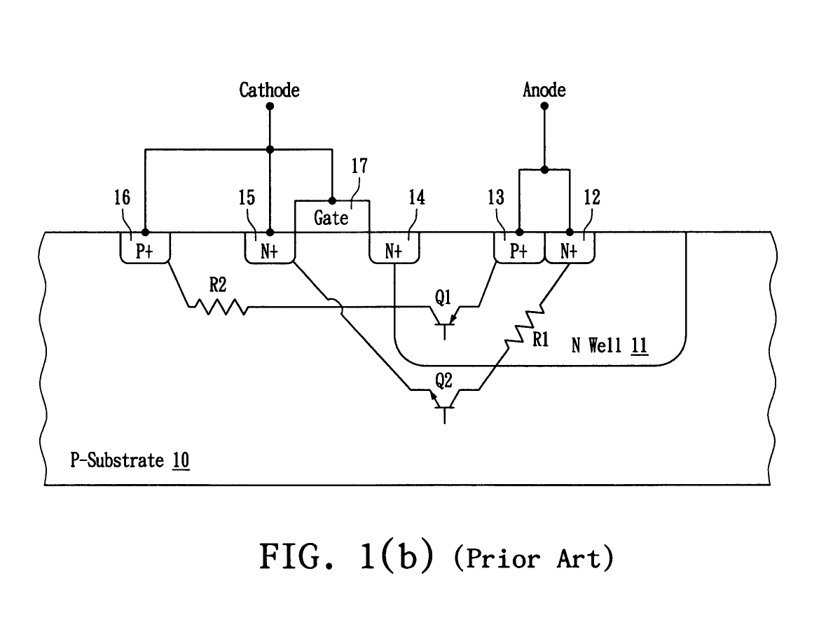

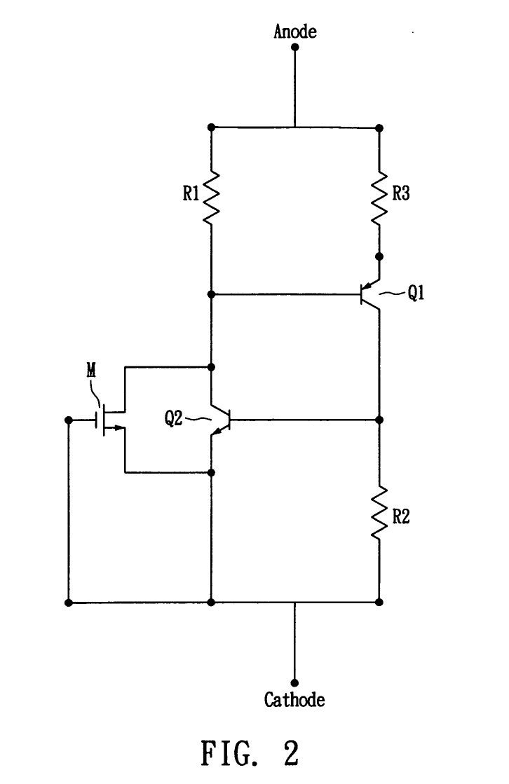

FIG. 2 is the equivalent circuit of the low voltage triggering silicon controlled rectifier (LVTSCR) of the present invention, which is based on the circuit of FIG. 1(a) and adds a resistor R3 between the anode and the parasitical bipolar PNP transistor Q1 of FIG. 1(a). The equivalent circuit of the LVTSCR of the present invention comprises a first resistor R1, a second resistor R2, a third resistor R3, a first transistor Q1, a second transistor Q2, and a third transistor M. The third resistor R3 is used to increase the holding voltage of the LVTSCR. The emitter, the collector, and the base of the first transistor Q1 are electrically connected to the anode (i.e., a first node) through the third resistor R3, to the cathode (i.e., a second node) through the second resistor R2, and to the anode through the first resistor R1, respectively. The base, the emitter, and the collector of the second transistor Q2 are electrically connected to the collector of the first transistor Q1, to the cathode, and to the base of the first transistor Q1, respectively. The gate, the source, and the drain of the third transistor M are electrically connected to the cathode, the cathode, and the collector of the second transistor Q2. Note that the breakdown voltage of the third transistor M is lower than that of the second transistor Q2.

The circuit of FIG. 2 operates as follows. Since the breakdown voltage of the NMOS transistor M is lower than that of the parasitical bipolar NPN transistor Q2, the NMOS transistor M is turned on first when the ESD event occurs. Meanwhile, the current acting on the NMOS transistor M turns on the parasitical bipolar NPN transistor Q2 that is coupled to the resistor R2. Then, the current flowing through the parasitical bipolar NPN transistor Q2 turns on the parasitical bipolar PNP transistor Q1. Further, the current acting on the parasitical bipolar PNP transistor Q1 enhances the current conduction through the parasitical bipolar NPN transistor Q2. Finally, the latch-up state is established. Presently, most current flows through the resistor R3, the parasitical bipolar PNP transistor Q1, and the parasitical bipolar NPN transistor Q2, to the cathode. Compared with FIG. 1(a), FIG. 2 presents an increased holding voltage by adding the resistor R3.

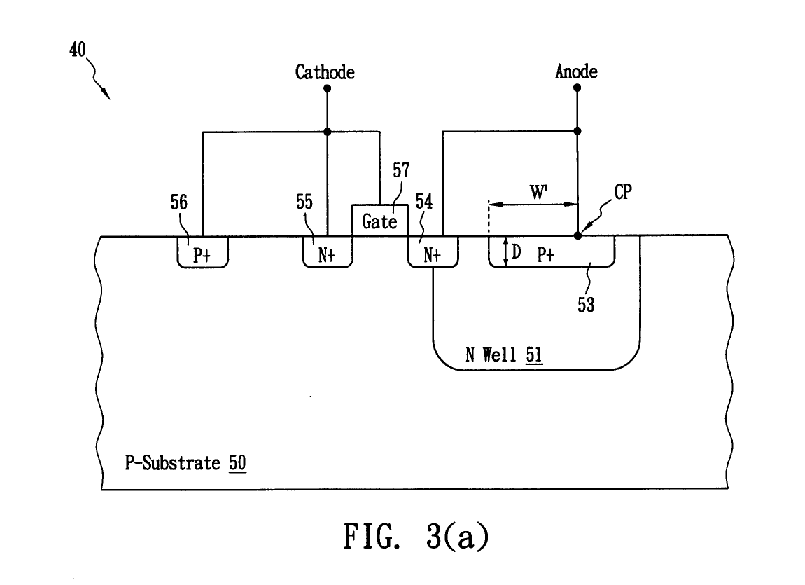

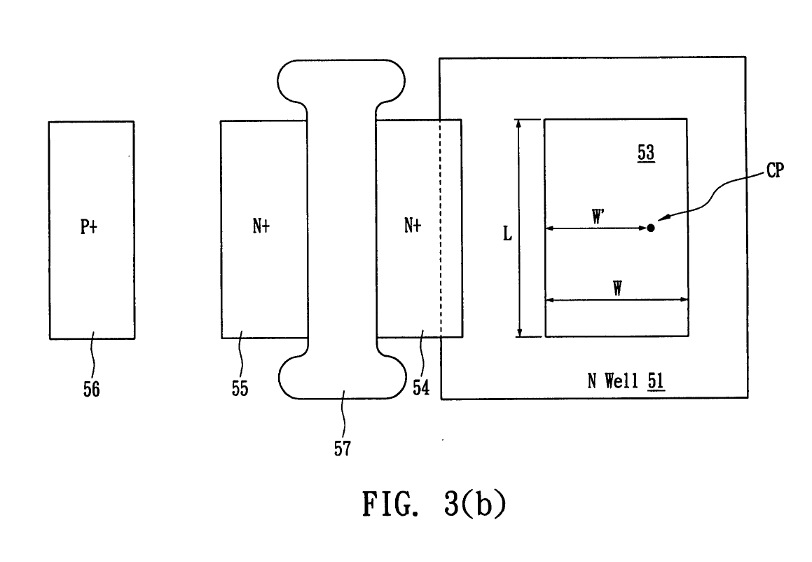

FIG. 3(a) illustrates a structural cross-section of one embodiment of the LVTSCR of the present invention. The LVTSCR 40 comprises a P-substrate 50 (i.e., a semiconductor substrate with a first conductive type) and a gate 57. The P-substrate 50 comprises an N-well 51 (i.e., a first doped region with a second conductive type), a P-type second doped region 53 (i.e., a second doped region with the first conductive type), an N-type third doped region 54 (i.e., a third doped region with the second conductive type), an N-type fourth doped region 55 (i.e., a fourth doped region with the second conductive type) and a P-type fifth doped region 56 (i.e., a fifth doped region with the first conductive type). The N-well 51 surrounds the P-type second doped region 53 whose resistance determines the holding voltage of the LVTSCR 40. The N-type third doped region 54 is disposed at the interface of the P-substrate 50 and the N-well 51. The doping concentrations of the N-type third doped region 54 and the N-type fourth doped region 55 are higher than that of N-well 51, and the doping concentrations of the P-type second doped region 53 and the P-type fifth doped region 56 are higher than that of the P-substrate 50. The gate 57 is disposed on the P-substrate 50 to control the conduction between the N-type third doped region 54 and the N-type fourth doped region 55. The N-type third doped region 54 and the P-type second doped region 53 are connected in parallel to the anode of the LVTSCR40. The gate 57, the N-type fourth doped region 55, and the P-type fifth doped region 56 are connected in parallel to the cathode of the LVTSCR 40. In operation, the anode is connected to the circuit to be protected and the cathode is grounded.

FIG. 3(b) is the top view of FIG. 3(a). The resistance of the P-type second doped region 53 is determined by the shape thereof (hence, the holding voltage of the LVTSCR 40 is determined), such as the doped depth D, the width W, or the length L. The length L and the width W of the P-type second doped region 53 were determined at mask-design stage; however, an equivalent width W′ is adjustable after the LVTSCR 40 is completed through CMOS manufacturing processes. The equivalent width W′ is defined as the distance from a contact point CP (where the lead connected to the anode touches the surface of the P-type second doped region 53) to the edge of the P-type second doped region 53, as shown in FIG. 3(b). Also, the resistance of the P-type second doped region 53 is adjustable by the doping concentration thereof, which is formed by an ion implantation process or a diffusion process.

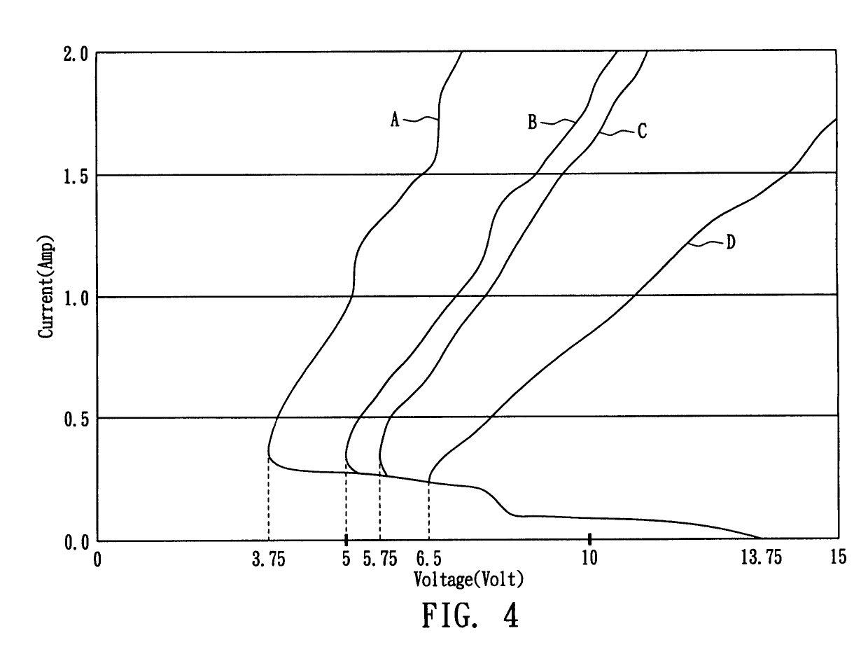

FIG. 4 shows the I-V curves of the LVTSCRs regarding FIG. 3(a) with different equivalent widths W′, where the ordinate indicates the current flowing from the anode to the cathode and the abscissa indicates the voltage between the anode and the cathode. Curves A, B, C, and D correspond to the I-V curve with the equivalent width W′ of 0.5 μm, 3 μm, 5μm, and 10 μm, respectively and correspond to the holding voltage of 3.75 volts, 5 volts, 5.75 volts, and 6.5 volts, respectively. From FIG. 4, longer equivalent widths W′ correspond to higher holding voltages. However, the triggering voltages of the four curves A, B, C, and D remain at about 13.75 volts. The reason is the triggering voltage of the LVTSCR 40 is determined by the breakdown voltage of the parasitical bipolar NPN transistor Q2, and the resistor R3 is not directly coupled to the parasitical bipolar NPN transistor Q2. Therefore, when the resistance of the resistor R3 changes (i.e., the equivalent width W′ changes in the current embodiment), the triggering voltage of the LVTSCR 40 is not influenced.

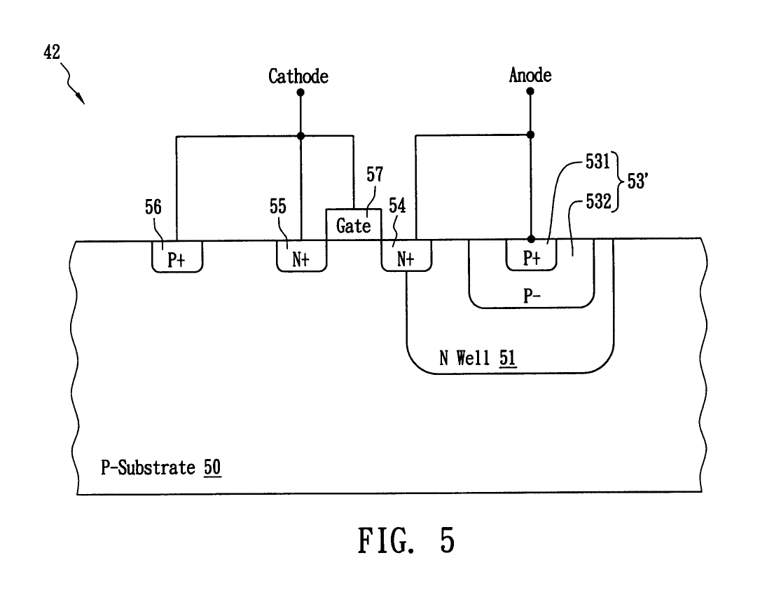

FIG. 5 illustrates a structural cross-section of another embodiment of the LVTSCR of the present invention. Similar to FIG. 3(a), the LVTSCR 42 comprises a P-substrate 50 and a gate 57, but the P-type second doped region 53 of FIG. 3(a) is replaced with a P-type second doped region 53′ comprising a P-type sixth doped region 531 and a P-type seventh doped region 532, where the P-type seventh doped region 532 surrounds the P-type sixth doped region 531 and the P-type sixth doped region 531 is connected to the anode. The doping concentration of the P-type sixth doped region 531 is higher than that of the P-type seventh doped region 532 and the doping concentration of the P-type fifth doped region 56 is higher than that of the P-substrate 50. The P-type second doped region 53′ and the N-type third doped region 54 are connected to the anode of the LVTSCR 42. The gate 57, the N-type fourth doped region 55, and the P-type fifth doped region 56 are connected to the cathode of the LVTSCR 42. In operation, the anode is connected to the circuit to be protected and the cathode is grounded.

Following the description above, the LVTSCR of the present invention exhibits a low triggering voltage (i.e., below 15 volts) and a high holding voltage (i.e., above 3.5 volts) and maintains the original triggering voltage. Therefore, the expected objectives of the present invention are achieved.

The above-described embodiments of the present invention are intended to be illustrative only. Numerous alternative embodiments may be devised by those skilled in the art without departing from the scope of the following claims.

We claim:

1. A low voltage triggering silicon controlled rectifier, comprising:
a semiconductor substrate with a first conductive type, said semiconductor substrate comprising:
a first doped region with a second conductive type;
a second doped region with said first conductive type, disposed in said first doped region and resistance thereof determining a holding voltage;
a third doped region with said second conductive type, disposed at an interface of said first doped region and said semiconductor substrate; and
a fourth doped region with said second conductive type; and
a gate disposed on said semiconductor substrate to control conduction between third doped region and fourth doped region, wherein said second doped region and said third doped region are connected in parallel to an anode, said gate and said fourth doped region being connected in parallel to a cathode.

2. The low voltage triggering silicon controlled rectifier of claim 1, wherein doping concentration of said second doped region is higher than doping concentration of said semiconductor substrate.

3. The low voltage triggering silicon controlled rectifier of claim 1, wherein semiconductor substrate further comprises:
a fifth doped region with said first conductive type, said fifth doped region, said gate, and said fourth doped region being connected in parallel to said cathode.

4. The low voltage triggering silicon controlled rectifier of claim 3, wherein doping concentration of said fifth doped region is higher than doping concentration of said semiconductor substrate.

5. The low voltage triggering silicon controlled rectifier of claim 1, wherein doping concentrations of said third doped region and said fourth doped region are higher than doping concentration of said first doped region.

6. The low voltage triggering silicon controlled rectifier of claim 1, wherein resistance of said second doped region is determined by doping concentration thereof.

7. The low voltage triggering silicon controlled rectifier of claim 1, wherein resistance of said second doped region is determined by a shape thereof.

8. The low voltage triggering silicon controlled rectifier of claim 1, wherein resistance of said second doped region is determined by an equivalent width thereof.

9. The low voltage triggering silicon controlled rectifier of claim 8, wherein said equivalent width is above 0.5 μm.

10. The low voltage triggering silicon controlled rectifier of claim 1, wherein said second doped region is formed by ion implantation or diffusion.

11. The low voltage triggering silicon controlled rectifier of claim 1, wherein the holding voltage is above 3.5 volts.

12. The low voltage triggering silicon controlled rectifier of claim 1, exhibiting a triggering voltage below 15 volts.

13. The low voltage triggering silicon controlled rectifier of claim 1, wherein said second doped region comprises:
a sixth doped region connected to said anode; and
a seventh doped region disposed in said first doped region and surrounding said sixth doped region.

14. The low voltage triggering silicon controlled rectifier of claim 13, wherein doping concentration of said sixth doped region is higher than doping concentration of said seventh doped region.

15. The low voltage triggering silicon controlled rectifier of claim 13, wherein resistance of said second doped region is determined by resistance of said sixth doped region and said seventh doped region.

16. A low voltage triggering silicon controlled rectifier circuit, comprising:
a third resistor increasing a holding voltage thereof;
a first transistor having an emitter electrically connected to a first node through said third resistor, a collector electrically connected to a second node through a second resistor, and a base electrically connected to the first node through a first resistor;
a second transistor having a base electrically connected to the collector of the first transistor, an emitter electrically connected to the second node, and a collector connected to the base of the first transistor; and
a third transistor having a gate and source electrically connected to the second node and a drain connected to the collector of the second transistor, wherein breakdown voltage of the third transistor is lower than breakdown voltage of the second transistor.

17. The low voltage triggering silicon controlled rectifier circuit of claim 16, exhibiting a triggering voltage below 15 volts.

18. The low voltage triggering silicon controlled rectifier circuit of claim 16, exhibiting a holding voltage above 3.5 volts.

19. The low voltage triggering silicon controlled rectifier circuit of claim 16, wherein the first transistor is a PNP transistor, the second transistor is an NPN transistor and the third transistor is an NMOS transistor.

20. The low voltage triggering silicon controlled rectifier circuit of claim 16, wherein the first and the second transistors are in a latch-up state to conduct charges from the first node to the second node.
